(19) United States
(12) Patent Application Publication
(10) Pub. No.: US 2013/0341378 A1
(43) Pub. Date: Dec. 26, 2013

(54) SYSTEM AND METHOD FOR INSPECTING FREE AIR BALL

(71) Applicants: Seok Khoon Lee, Seremban (MY); Lai Cheng Law, Bandar Sg Long (MY); Weng Foong Yap, Shah Alam (MY)

(72) Inventors: Seok Khoon Lee, Seremban (MY); Lai Cheng Law, Bandar Sg Long (MY); Weng Foong Yap, Shah Alam (MY)

(73) Assignee: Freescale Semiconductor, Inc., Austin, TX (US)

(21) Appl. No.: 13/530,123

(22) Filed: Jun. 22, 2012

(51) Int. Cl. H01L 21/66; H04N 7/18

(52) U.S. Cl. 228/103; 348/92; 348/E07.085

(57) ABSTRACT

A system for inspecting a free air ball (FAB) formed during a wire bonding process includes a torch for forming a FAB at a tip of a bonding wire held by a capillary. A camera is positioned near the FAB formation location and captures a color image of the FAB. A ball formation monitor inspects the image to determine a composition of an outer surface of the FAB and inhibits bonding of the FAB to a contact element based on a result of the inspecting. The system is particularly useful for bonding Copper wire plated with Palladium, where bonding of the FAB to the contact element is inhibited if the Copper is exposed.

### BACKGROUND OF THE INVENTION

The present invention relates to integrated circuit (IC) device assembly equipment and, more particularly, to a system and method for inspecting a free air ball formed during a wire bonding process.

Many current semiconductor devices are assembled using a wire bonding process in which contact pads of an integrated circuit are connected to contact pads of a lead frame or substrate with bond wires. The bond wires are small and thin and must have good electrical characteristics. While bond wires formed of Gold have good electrical characteristics, Gold has become very expensive and therefore wires formed of Copper have been gaining in popularity. However, Copper oxidizes very quickly so bond wires formed of Copper and plated with a protective metal coating such as Palladium are now being used. Copper also reacts adversely when in contact with mold compound, which can result in poor quality wire bonds.

In ball bonding, a free air ball or “FAB” is formed at the tip of the bond wire with a torch. FIG. 1 is a photograph of a free air ball (FAB) 10 formed at the tip of a Palladium coated Copper bond wire. The FAB 10 has an even coating of Palladium over the FAB 10. FIG. 2 is a photograph of another FAB 20 also formed at the tip of a Palladium coated Copper wire. The FAB 20 unfortunately does not have an even coating of Palladium 22, but rather has some exposed Copper 24. Such exposed Copper 24 can compromise the bond or attachment of the bond wire to the contact pad (not shown). Accordingly, it would be advantageous to be able to monitor FAB formation prior to bonding the FAB to a contact pad.

### BRIEF DESCRIPTION OF THE DRAWINGS

The invention, together with objects and advantages thereof, may best be understood by reference to the following description of preferred embodiments together with the accompanying drawings in which:

FIG. 1 is a photograph of a free air ball formed at the tip of a Palladium coated Copper wire;

FIG. 2 is a photograph of another free air ball formed at the tip of a Palladium coated Copper wire with some of the underlying Copper exposed;

FIG. 3 is a side view in partial cross-section of system for forming a free air ball in accordance with an embodiment of the present invention;

FIG. 4 is a high level schematic block diagram of a system in accordance with an embodiment of the present invention; and

FIG. 5 is a flow chart illustrating some of the steps performed when analyzing a free air ball formed by the system of FIGS. 3 and 4, in accordance with an embodiment of the present invention.

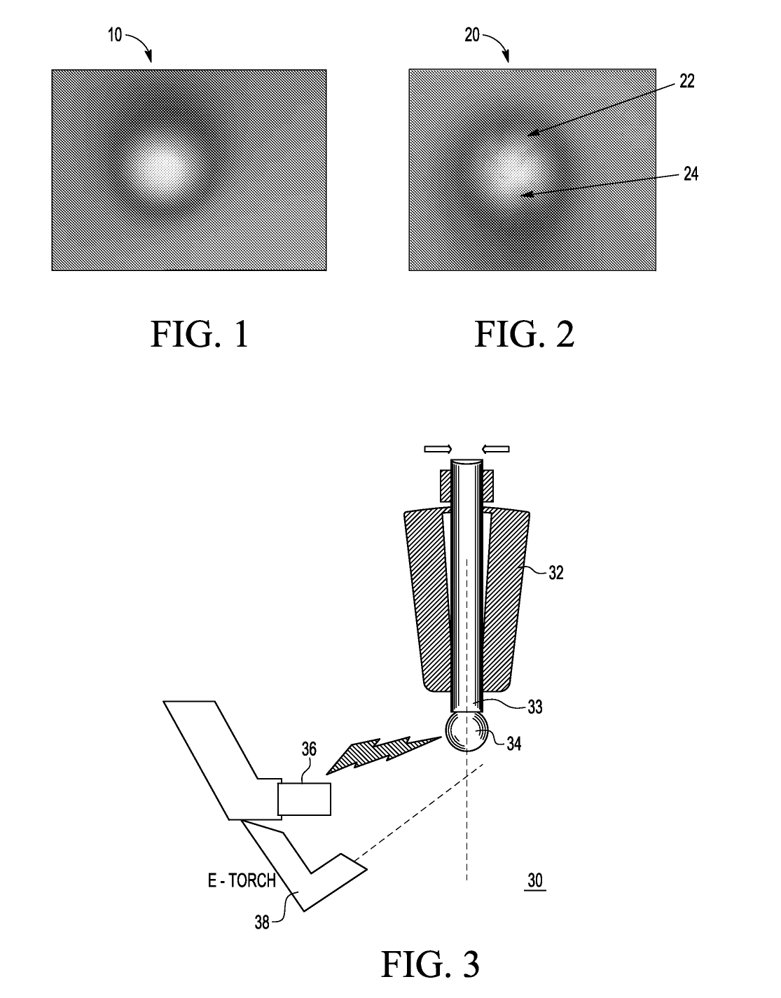

### DETAILED DESCRIPTION OF PREFERRED EMBODIMENTS

The detailed description set forth below in connection with the appended drawings is intended as a description of presently preferred embodiments of the invention, and is not intended to represent the only forms in which the present invention may be practised. It is to be understood that the same or equivalent functions may be accomplished by different embodiments that are intended to be encompassed within the spirit and scope of the invention. In the drawings, like numerals are used to indicate like elements throughout. Furthermore, terms “comprises,” “comprising,” or any other variation thereof, are intended to cover a non-exclusive inclusion, such that module, circuit, device components, structures and method steps that comprises a list of elements or steps does not include only those elements but may include other elements or steps not expressly listed or inherent to such module, circuit, device components or steps. An element or step proceeded by “comprises . . . a” does not, without more constraints, preclude the existence of additional identical elements or steps that comprises the element or step.

In one embodiment, the present invention provides a system for inspecting a free air ball formed during a wire bonding process. The system includes a torch for forming a free air ball at a tip of a bonding wire held by a capillary, and a camera positioned near the free air ball formation location for capturing an image of the free air ball prior to bonding the free air ball to a contact element. A ball formation monitor is provided for inspecting the image to determine a composition of an outer surface of the free air ball, and inhibiting the bonding of the free air ball to the contact element based on a result of said inspecting. In a preferred embodiment of the invention, the camera is a color camera.

In another embodiment, the present invention provides a method for bonding a wire to a contact element, wherein the wire is held within a capillary of a wire bonding apparatus. The method includes the steps of forming a free air ball at a tip of the wire; capturing an image of the free air ball with a camera; inspecting the image to determine a composition of an outer surface of the free air ball; bonding of the free air ball to a contact element based on a result of said inspecting; and inhibiting said bonding of the free air ball to the contact element depending on a result of said inspecting.

Referring to FIG. 3, a system 30 for inspecting a free air ball formed during a wire bonding process is shown. A capillary 32 holds a bond wire 33 with a free air ball or FAB 34 formed at a tip of the bond wire 33. The bond wire 33 may be a Palladium coated Copper wire. As previously discussed, such wire is commercially available and currently used in semiconductor device assembly and packaging processes. A torch 36 is moved into proximity with the bond wire 33 to form the FAB 34, as is known by those of skill in the art. The capillary 32 and torch 36 both are well known in the art and therefore detailed descriptions thereof are not necessary for a complete understanding of the present invention. In accordance with an embodiment of the present invention, a camera 38 is positioned near the FAB 34 formation location for capturing an image of the FAB 34 prior to bonding the FAB 34 to a contact element such as a bond pad of an integrated circuit formed on a semiconductor die. In a preferred embodiment of the invention, the camera 38 is mounted to the torch 36 so that the camera 38 can be readily moved into proximity with the FAB 34. A camera 38 also is small in size so that it does not interfere with the wire bonding process. The camera 38 preferably is a color camera capable of capturing a color image of the FAB 34. Suitable miniature or micro color cameras are commercially available, such as the KX-121 CCD camera with a pinhole lens made by Panasonic Corporation of Osaka, Japan.

In a preferred embodiment, the camera 38 is attached to the torch 36 so that the camera 38 and the torch 36 are aligned so that the camera 38 will not collide with the capillary 32 or otherwise impinge on the wire bonding process. In one embodiment, the camera 38 is adjustable so that it can capture multiple images of the FAB 34 at different angles.

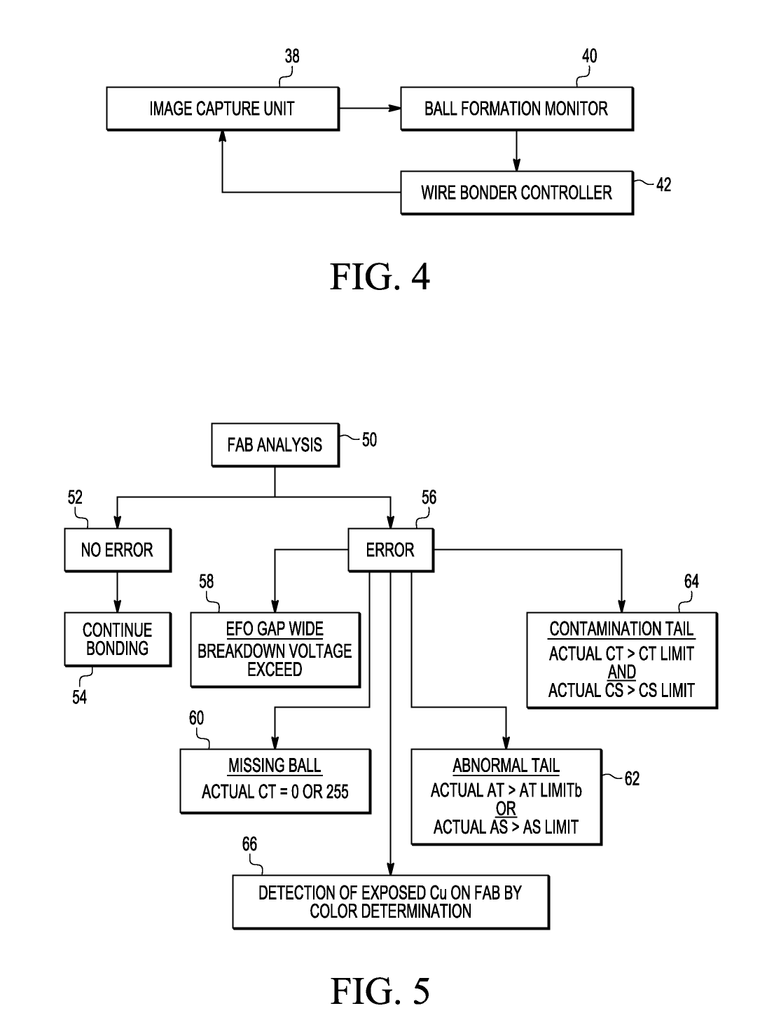

Referring to FIG. 4, the system 30 also includes a ball formation monitor 40 coupled between an image capture unit, i.e., the camera 38 and a wire bonder controller 42. The ball formation monitor 40 inspects the image captured by the camera 38 to determine a composition of an outer surface of the FAB 34. That is, a color image is used to detect if any of the Copper of the bond wire 33 is exposed. In one embodiment of the invention, if the ball formation monitor 40 determines that any Copper is exposed on the FAB 34, the ball formation monitor 40 issues an alert signal, such as a visual message and/or audio signal to a console of the wire bonder. An operator can then review the captured image and adjust the EFO (electronic flame off) parameters of the wire bonder so that FAB formation does not expose the Copper core of the bond wire 33. Detection of Copper exposure also can inhibit the bonding of the FAB 34 to the contact element (i.e., die bond pad) based on a result of said inspecting. Detection of exposed Copper can be readily determined using a color image of the FAB 34.

FIG. 5 is a flow chart of a portion of the wire bonding process performed by a wire bonding apparatus modified to include the camera 38 and appropriate software for analyzing the captured image of the FAB 34 prior to attaching the FAB 34 to a die bond pad (not shown). Block 52 indicates that no error is determined at the analysis block 50, so the wire bonding apparatus continues with bonding operations at block 54. Detection of an error is shown at block 56 and blocks 58-66 illustrate some of the error conditions that may be detected. For example, block 58 indicates that a break down voltage is exceeded, block 60 indicates detection of missing ball, block 62 indicates detection of an abnormal tail, and block 64 indicates detection of a contaminated tail. The EFO break voltage (block 58) is a sensitivity test for short tail occurrence. If the breakdown voltage is greater than the EFO Gap Voltage the machine will generate an ‘EFO Gap Wide’ warning for short tail. EFO gap voltage is the EFO breakdown voltage checking the threshold voltage, which means the higher the value entered for EFO gap voltage, the lesser the sensitivity for real short tail issue. Such error detection is already available in commercially available wire bonding apparatuses. However, block 66 indicates detection of exposed Copper on the FAB 34, in accordance with an embodiment of the present invention, by analyzing the color of the FAB 34.

By analyzing the color of the FAB 34 before the FAB 34 is bonding to a die bond pad, poor quality bonds can be prevented and the wire bonder parameters can be immediately adjusted during manufacturing, rather than having to scrap a lot of already assembled or partially assembled devices where it is determined that there are faulty bonds from analysis performed on such already assembled or partially assembled devices. The present invention can be applied to wire bonding processes using wires other than Palladium coated Copper wires as long as there is a color difference between the wire core and the coating or plating material.

The description of the preferred embodiments of the present invention has been presented for purposes of illustration and description, but is not intended to be exhaustive or to limit the invention to the forms disclosed. It will be appreciated by those skilled in the art that changes could be made to the embodiments described above without departing from the broad inventive concept thereof. It is understood, therefore, that this invention is not limited to the particular embodiment disclosed, but covers modifications within the spirit and scope of the present invention as defined by the appended claims.

1. (canceled)

2. (canceled)

3. (canceled)

4. (canceled)

5. (canceled)

6. A system for inspecting a free air ball formed during a wire bonding process, the system comprising:
a torch for forming a free air ball at a tip of a bonding wire held by a capillary, wherein the bond wire comprises a copper core plated with palladium;
a camera directly attached to the torch and positioned near the free air ball formation location for capturing a color image of the free air ball prior to bonding the free air ball to a contact element; and
a ball formation monitor for inspecting the image to determine a composition of an outer surface of the free air ball to detect if any copper is exposed and inhibiting the bonding of the free air ball to the contact element based on a result of said inspecting.

7. (canceled)

8. (canceled)

9. The system for inspecting a free air ball of claim 7, wherein the contact element comprises a die bonding pad.

10. A method for bonding a wire to a contact element, wherein the wire is held within a capillary of a wire bonding apparatus, the method comprising:
forming a free air ball at a tip of the wire;
capturing an image of the free air ball with a camera;
inspecting the image to determine a composition of an outer surface of the free air ball;
bonding of the free air ball to a contact element based on a result of said inspecting; and
inhibiting said bonding of the free air ball to the contact element depending on a result of said inspecting.

11. The method of claim 10, wherein the free air ball is formed with a torch.

12. The method of claim 11, wherein the camera captures a color image of the free air ball.

13. The method of claim 12, wherein the bond wire comprises a copper core plated with palladium and the ball formation monitor inspects the image to detect if any copper is exposed.

14. The method of claim 12, wherein the camera is attached to the torch.
